(19) United States
(12) Patent Application Publication
(10) Pub. No.: US 2021/0165013 A1
(43) Pub. Date: Jun. 3, 2021

(54) ADAPTIVE FILTER FOR MOTOR SPEED MEASUREMENT SYSTEM

(71) Applicant: Hamilton Sundstrand Corporation, Charlotte, NC (US)

(72) Inventor: Andrei DINU, Leicester Leicestershire (GB)

(21) Appl. No.: 17/004,167

(22) Filed: Aug. 27, 2020

(30) Foreign Application Priority Data
Dec. 3, 2019 (EP) 19275138.6

(51) Int. Cl. G01P 3/48; G01D 5/14; G01D 5/22; G01B 7/30; G01P 1/00; G05B 19/416

(52) U.S. Cl. CPC G01P 3/4802; G01D 5/145; G01D 5/2291; G05B 2219/37312; G01P 1/00; G05B 19/416; G01B 7/30

(57) ABSTRACT

A filter for motor speed measurement signals includes one or more resonators configured to filter signals having a frequency that is proportional by a predetermined factor to the frequency of the motor whose speed is measured.

### FOREIGN PRIORITY

This application claims priority to European Patent Application No. 19275138.6 filed Dec. 3, 2019, the entire contents of which is incorporated herein by reference.

### TECHNICAL FIELD

The present disclosure is concerned with motor drive systems and with accurately determining the speed of a motor driven by such a system.

### BACKGROUND

A drive system is typically commanded either to drive the motor to rotate at a given speed or to rotate to a given position. Typical motor drive applications use resolvers or Hall sensors to measure both motor speed and position which are fed back to control the drive system.

It is important to measure the motor speed and position accurately as the accuracy of measurement impacts directly on the dynamic performance of the drive. With known resolvers and Hall sensors, the actual motor speed/position information is derived by demodulating the sensor feedback signals.

Resolvers are extremely accurate, rugged, absolute transducers of position. They are based on fundamental transformer principles, with one primary winding plus two secondary windings, which are oriented in quadrature (90°) with respect to each other. The effective turns ratio and polarity between the primary and secondary windings varies depending on the angle of the shaft. The primary winding is excited with a reference AC waveform at constant amplitude and frequency, (typically around 10 kHz) and the outputs of the secondary windings will have the same frequency but variable amplitude as a function of rotor position. The peak voltages of the secondary windings will vary as the shaft rotates, and will follow the profile of trigonometric functions Sin and Cos. By demodulating these outputs using the primary excitation signal as a reference, the resolver circuitry can provide a high-resolution readout of the shaft angle and, thus, motor speed/position.

Resolvers are rugged and are useful in challenging environments such as aircraft applications.

However, resolvers tend to be large and relatively costly compared to alternatives, and require a relatively large amount of power, which is often unacceptable in low-power applications. They also require relatively complex circuitry for generation and demodulation of the AC waveforms.

A smaller, lighter electronic device used for position sensing is a Hall sensor. Hall-effect devices can be used to sense the presence or absence of a nearby magnetic field. They produce voltage across an electrical semiconductor, at right angles to an electric current in the conductor and a magnetic field perpendicular to the current.

Similar to resolvers, Hall sensor encoders generate two feedback signals—sin and cos—indicative of the angle of the rotor and thus indicative of the motor speed. However, Hall sensors generate simple sin and cos signals. Resolvers use the sin and cos signals to modulate an excitation signal. In both cases, though, the signals are filtered and amplified and distortions occur. Such distortions include DC offsets and amplitude imbalances between the sin and cos signals caused by the analogue signal conditioning circuits that separate the sensor from the digital control system. Further, with Hall sensors, the accuracy can be affected by how the sensors are mounted and by their mechanical and electrical tolerances. This can lead to the sin and cos signals not having exactly a 90 deg. phase shift—so-called ‘quadrature errors’.

Any distortions in the feedback signals will propagate through the demodulation algorithm and cause ripple in the measured motor speed.

There is a need to improve the accuracy of motor position and speed measurement.

### SUMMARY

It is known that the measured speed ripple includes harmonics with frequency and amplitude which are proportional to the motor speed. DC offsets give rise to a speed ripple with frequency equal to the motor mechanical frequency. Amplitude imbalances and quadrature errors give rise to a ripple frequency that is twice the motor mechanical frequency. If more than one distortion type is present, the measured speed ripple will be the resulting sum of all the ripples.

The inventor has made use of the fact that the ripple is predictable based on the motor speed to create a filter to remove such ripple. In other words, an adaptive filter can be designed to remove ripple, without removing other useful information, from the speed measurement based on knowledge of the characteristics of the ripple. In this way, the filter is arranged to post-process the output provided from the algorithm that demodulates the sensor signals. This solution is able to filter out speed measurement ripple that will be encountered in most practical situations.

According to one aspect, there is provided a filter for motor speed measurement signals, comprising one or more resonators configured to filter signals having a frequency that is proportional by a predetermined factor to the frequency of the motor whose speed is measured. The one or more resonators is/are configured to have a resonant frequency proportional to the frequency of the motor. Each resonator is configured as a closed loop system comprising two variable-gain integrators connected in anti-parallel.

In one possible configuration, the filter has one resonator configured to filter signals having a frequency equal to the frequency of the motor.

In another possible configuration, the filter comprises one resonator configured to filter signals having a frequency equal to two times the frequency of the motor.

According to a second aspect, there is provided a speed position measuring system comprising a sensor arranged to determine the speed of rotation of a motor and to provide a speed measurement signal and a filter as described above arranged to receive the speed measurement signal and to filter ripple signals therefrom being signals having a frequency that is proportional by a predetermined factor to the frequency of the motor.

Preferably, the sensor comprises a resolver or a Hall Effect sensor.

The system may also comprise a demodulator to demodulate the output of the sensor to provide the speed measurement signal.

A motor drive system is also provided comprising motor drive circuitry to control a motor to rotate at a given speed, and a speed position measuring system as described above in a feedback loop between the sensor and the motor drive circuitry.

### BRIEF DESCRIPTION OF THE DRAWINGS

FIG. 1 is a simple representation of a single notch filter configuration in accordance with an embodiment of this disclosure.

FIG. 2 is a simple representation of a double notch filter configuration in accordance with an embodiment of this disclosure.

FIG. 3 is a simple representation of the configuration of a resonator such as shown in FIG. 1 or 2.

FIG. 4 shows the poles and zeroes as well as the frequency response of a single-notch filter.

FIG. 5 shows a more detailed diagram of a single-notch filter.

### DETAILED DESCRIPTION

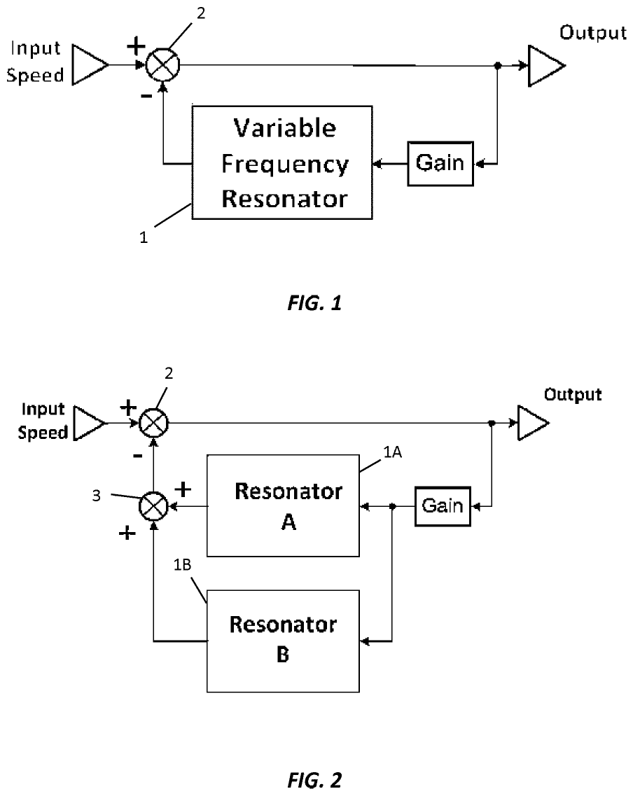

FIG. 1 shows a filter configuration according to an embodiment of the present disclosure. The filter is configured to filter out ripple from a speed signal derived from a motor speed sensor (not shown) such as (as discussed above) a resolver or a Hall sensor. The measured speed signal will include ripple due to feedback distortions caused by the speed sensors and other analogue interface components.

The speed signal from the demodulation algorithm is usually provided as feedback to the speed control loop of the motor drive system (not shown).

The filter in the embodiment of FIG. 1, a so-called ‘single-notch’ filter includes a variable frequency resonator 1 provided on a feedback path. The resonator 1 is configured, based on the average measured motor speed, knowing how the ripple is related to that speed, to remove the ripple from the input signal applied to subtracter 2.

If two different ripple frequencies are to be removed, the filter can be designed as a double-notch filter as shown in FIG. 2 comprising two resonators (1A and 1B) and two adders/subtracters 2,3.

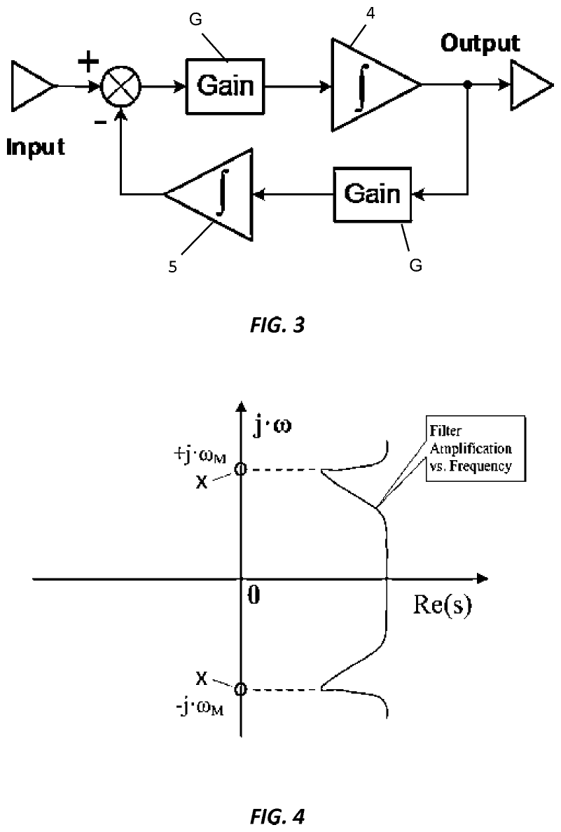

The resonator(s) has/have a structure as shown in FIG. 3. As shown, each resonator is a closed loop system comprising two variable-gain integrators 4,5 connected in anti-parallel.

As mentioned above, the ripple frequency is known to be proportional to the mechanical frequency of the motor by a factor dependent on the type of distortion as discussed above—for DC offsets, the ripple frequency is equal to the motor frequency; for other distortions it is double the motor frequency.

For a single notch filter as shown in FIG. 1, the gain of the resonator should be such that the resonant frequency of the resonator is the same as the motor mechanical frequency as that will be the frequency of the ripple to be removed from the speed signal (for the first type of distortion mentioned above).

The resonator 1 of FIG. 1 has a configuration as shown in FIG. 3. If both integrators 4,5 have the same gain G=ω_{M}=2π·f_{M} (where f_{M} is the motor mechanical frequency) then the transfer function of the resonator is as follows:

$${H}_{OSC} ( s ) = \frac{\frac{{ω}_{M}}{S}}{1 + \frac{{ω}_{M}}{S} \cdot \frac{{ω}_{M}}{S}} = \frac{{ω}_{M} \cdot S}{{S}^{2} + {ω}_{M}^{2}}$$

Thus, the resonant frequency is equal to the motor mechanical frequency, which covers the first type of signal distortion mentioned above. The closed loop filter transfer function is the following (where K₃ is the filter gain in FIG. 1):

$${H}_{NJ} ( s ) = \frac{1}{1 + {K}_{3} \cdot \frac{{ω}_{M} \cdot s}{{s}^{2} + {ω}_{M}^{2}}} = \frac{{s}^{2} + {ω}_{M}^{2}}{{s}^{2} + {ω}_{M}^{2} + {K}_{3} {ω}_{M} \cdot s}$$

Gain K₃ needs to be tuned such that the positions of the two filter poles are close to the positions of the filter zeroes in order to achieve very narrow frequency notches (see FIG. 4). The real components of the poles need to be small negative values. The imaginary components of the poles need to be in approximate alignment to the imaginary components of the zeroes (see again FIG. 4). The filter poles are:

$${p}_{1 , 2} = \frac{- {K}_{3} {ω}_{M} \pm {ω}_{M} \sqrt{{K}_{3}^{2} - 4}}{2}$$

The condition for the filter stability is K₃<2. Very small K₃ produces very good vertical alignment between poles and zeroes. However, this also reduces the stability margin of the filter by bringing the poles very close to the imaginary axis. Larger K₃ improves the filter stability but also increases the width of the frequency notches.

A good compromise is produced by K₃=0.25. The resulting poles are:

p_{1,2}=−0.125·ω_{M}±0.99·jω_{M}

The amplitude of the speed oscillations caused by the Sin and Cos distortions is proportional to the motor speed. Therefore, almost no oscillations are present in the measured speed when the motor speed if very low. However the resonator inside the filter will always oscillate after any fast transient on the input signal. For instance, this can happen when the motor speed decreases rapidly from high speed to low speed.

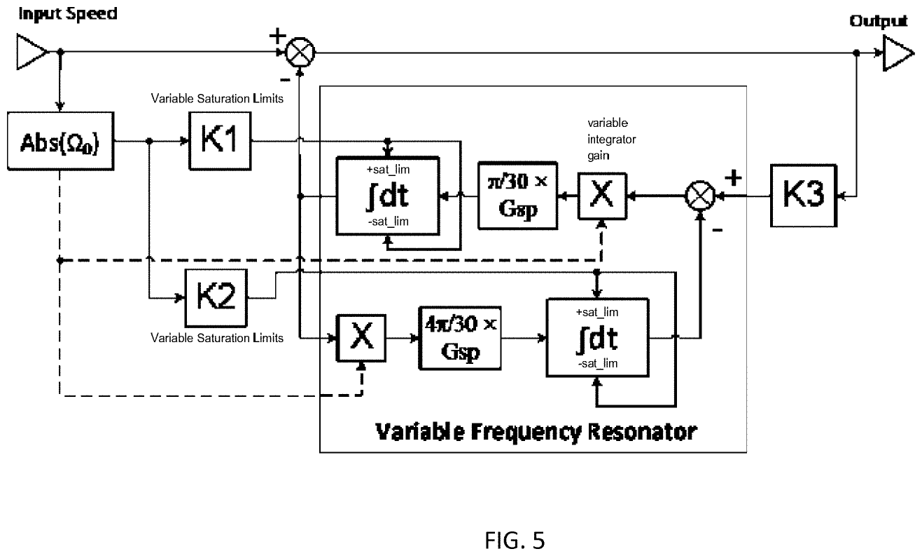

The full filter configuration needs to include variable saturation limits for the two integrators to eliminate unwanted oscillations in the resonator. The integrator limits will be proportional to the absolute value of the motor speed as indicated in FIG. 5. The proportionality factors K₁ and K₂ are set based on the following considerations:
Gain K₁ needs to be set just above the amplitude of the oscillations in the input speed measurement in order to allow these oscillations to be removed by the negative feedback loop of the filter.
The steady state value of the second integrator is “Input Speed×K₃”.

Therefore gain K₁ needs to be set slightly larger than K₂ to provide margin for the oscillations that occur when speed ripple is being eliminated by the filter.

The recommended value is:

K₁=1.251K₂=0.3125

A second resonator can be added to the filter if two frequencies need to be removed from the input signal (see FIG. 2). The integrator gains of the second resonator are set to G=2·ω_{M}.

The filter of this disclosure provides improved motor speed measurement accuracy when the position sensor outputs are affected by sensor distortions. The filter is also immune to variations in analogue component parameters of the drive system.

The described embodiments are by way of example only. The scope of this disclosure is limited only by the claims.

1. A filter for motor speed measurement signals, the filter comprising:
one or more resonators configured to filter signals having a frequency that is proportional by a predetermined factor to the frequency of the motor whose speed is measured.

2. The filter of claim 1, wherein the one or more resonators is/are configured to have a resonant frequency proportional to the frequency of the motor.

3. The filter of claim 1, wherein each resonator is configured as a closed loop system comprising two variable-gain integrators connected in anti-parallel.

4. The filter of claim 1, wherein one the one or more one resonators is configured to filter signals having a frequency equal to the frequency of the motor.

5. The filter of claim 4, wherein one the one or more one resonators is one resonator configured to filter signals having a frequency equal to two times the frequency of the motor.

6. A speed position measuring system comprising:
a sensor arranged to determine the speed of rotation of a motor and to provide a speed measurement signal; and
a filter as recited in claim 1,
wherein the filter is arranged to receive the speed measurement signal and to filter ripple signals therefrom being signals having a frequency that is proportional by a predetermined factor to the frequency of the motor.

7. The speed position measuring system of claim 6, wherein the sensor comprises a resolver.

8. The speed position measuring system of claim 6, wherein the sensor comprises a Hall effect sensor.

9. The speed position measuring system of claim 6, further comprising a demodulator to demodulate the output of the sensor to provide the speed measurement signal.

10. A motor drive system comprising:
motor drive circuitry to control a motor to rotate at a given speed; and
a speed position measuring system that includes:
a sensor arranged to determine the speed of rotation of a motor and to provide a speed measurement signal; and
a filter as recited in claim 1,
wherein the filter is arranged to receive the speed measurement signal and to filter ripple signals therefrom being signals having a frequency that is proportional by a predetermined factor to the frequency of the motor,
wherein the filter is in a feedback loop between the sensor and the motor drive circuitry.

11. The system of claim 10, further comprising the motor.
